(19) United States
(12) Patent Application Publication
(10) Pub. No.: US 2014/0248784 A1
(43) Pub. Date: Sep. 4, 2014

(54) MICROWAVE PROCESSING APPARATUS AND MICROWAVE PROCESSING METHOD

(71) Applicant: Tokyo Electron Limited, Tokyo (JP)

(72) Inventors: Hiroyuki HAYASHI, Yamanashi (JP); Sumi TANAKA, Yamanashi (JP)

(73) Assignee: Tokyo Electron Limited, Tokyo (JP)

(21) Appl. No.: 14/194,318

(22) Filed: Feb. 28, 2014

(30) Foreign Application Priority Data
Mar. 1, 2013 (JP) 2013-040638
Nov. 20, 2013 (JP) 2013-239645

(51) Int. Cl. H01L 21/324; H05B 6/64; H01L 21/67

(52) U.S. Cl. CPC H01L 21/324; H01L 21/67115; H05B 6/6491
USPC 438/795; 219/759; 219/686

(57) ABSTRACT

A microwave processing apparatus includes a processing chamber configured to accommodate an object to be processed, a support member configured to support the object by contact with the object in the processing chamber, and a microwave introducing unit configured to generate a microwave for processing the object and introduce the microwave into the processing chamber. The microwave processing apparatus further includes a heat absorbing layer provided on a wall surface of a member facing the object supported by the supporting member in the processing chamber. The heat absorbing layer is made of a material that transmits the microwave and has an emissivity higher than an emissivity of the member facing the object.

### CROSS-REFERENCES TO RELATED APPLICATIONS

The present invention claims priority of Japanese Patent Application Nos. 2013-040638 and 2013-239645 respectively filed on Mar. 1 and Nov. 20, 2013, the entire contents of which are incorporated herein by reference.

### FIELD OF THE INVENTION

The present invention relates to a microwave processing apparatus for performing a process on an object to be processed by introducing a microwave into a processing chamber, and a microwave processing method for irradiating a microwave to the object in the microwave processing apparatus.

### BACKGROUND OF THE INVENTION

Recently, an apparatus using a microwave is suggested as an apparatus for performing heat treatment on a substrate such as a semiconductor wafer or the like. The heat treatment using a microwave may be internal heating, local heating and selective heating and thus is advantageous in its processing efficiency compared a conventional annealing apparatus such as a lamp heating or a resistance heating. For example, when doping atoms are activated by using microwave heating, a microwave directly acts on the doping atoms. Therefore, it is advantageous in that surplus heating does not occur and diffusion of a diffusion layer can be suppressed. Further, the heating by irradiation of a microwave is advantageous in that an annealing process can be performed at a relatively low temperature and an increase a thermal budget can be suppressed compared to she conventional lamp heating or resistance hating. However, it is difficult to control, an entire temperature of the substrate only by an output of a microwave, and an annealing process in which heating using a microwave and cooling are balanced is required in order to prevent an excessive temperature increase.

In order to cool the substrate that is being heated or has been heated by the microwave irradiation in the processing chamber of the microwave processing apparatus, it is considered to employ a gas cooling method for introducing a cooling gas into the processing chamber. However, in the case of the gas cooling method, a cooling efficiency in accordance with a flow rate of the cooling gas considerably depends on a capacity in the processing chamber. Therefore, the most effective way to improve the substrate cooling efficiency in the gas cooling method is to decrease the volume in the processing chamber of the microwave processing apparatus. However, in the microwave processing apparatus, the shape or the size of the processing chamber affects electromagnetic field distribution. Therefore, it is not practical to change the design in the volume or the shape of the processing chamber in order to improve the cooling efficiency. Further, the efficiency of cooling the substrate by the cooling gas is easily changed by a gas flow rate or a gas flow in the processing chamber. Thus, it is difficult to obtain a uniform and stable cooling effect in the surface of the substrate.

In order to improve the cooling efficiency in the case of cooling the substrate in the processing chamber, there is suggested a substrate cooling apparatus in which a heat absorption layer formed of a black oxide film is provided at an inner surface of a cover which faces a processing space and absorbs radiant heat from the substrate (see, e.g., Japanese Patent Application Publication No. H09-007925 (e.g., FIG. 2)). However, the substrate cooling apparatus disclosed in Japanese Patent Application Publication No. H09-007925 is an apparatus used only for cooling a substrate and thus does not perform a microwave process on the substrate.

The microwave has a long wavelength of several tens of mm and has a property of easily forming a standing wave in the processing chamber. Thus, in the microwave processing apparatus for processing a substrate with a microwave, when a heat absorption layer for improving a substrate cooling efficiency is provided in the processing chamber without considering properties of the microwave, the intensity of the electromagnetic field in the surface of the substrate becomes non-uniform, and the heating temperature becomes non-uniform.

### SUMMARY OF THE INVENTION

In view of the above, the present invention provides a microwave processing apparatus capable effectively cooling an object to be processed without significant affecting behavior of a microwave in a processing chamber.

In accordance with an aspect of the present invention, there provided a microwave processing apparatus including: a processing chamber configured to accommodate an object to be processed, the processing chamber having an upper wall, a bottom wall and a sidewall; a support member configured to support the object by contact with the object in the processing chamber; a microwave introducing unit configured to generate a microwave for processing the object and introduce the microwave into the processing chamber; and a heat absorbing layer provided on a wall surface of a member facing the object supported by the supporting member in the processing chamber, the heat absorbing layer made of a material that transmits the microwave and has an emissivity higher than an emissivity of the member facing the object.

In accordance with an aspect of the present invention, there is provided a microwave processing method, wherein in the processing chamber of the microwave processing apparatus described above, the microwave is irradiated to the object.

### BRIEF DESCRIPTION OF THE DRAWINGS

The objects and features of the present invention will become apparent from the following description of embodiments, given in conjunction with the accompanying drawings, in which:

FIG. 1 is a cross sectional view showing a schematic configuration of a microwave processing apparatus in accordance with a first embodiment of the present invention;

FIG. 2 explains a schematic configuration of a high voltage power supply unit of a microwave introducing unit in the first embodiment of the present invention;

FIG. 3 is a top view showing a top surface of a ceiling portion or the processing chamber shown in FIG. 1;

FIG. 4 is an enlarged cross sectional view showing a heat absorption layer and the ceiling portion of the processing chamber shown in FIG. 1;

FIG. 5 is an enlarged cross sectional view showing another example of the heat absorption layer and the ceiling portion of the processing chamber shown in FIG. 1;

FIG. 6 is a graph showing a measurement result of a semiconductor wafer temperature in a modification in which a hard alumite film is provided as a heat absorption layer;

FIG. 7 explains a configuration of the control unit shown in FIG. 1;

FIG. 8 is a cross sectional view showing a schematic configuration of a microwave processing apparatus in accordance with a second embodiment of the present invention; and

FIG. 9 is a graph showing a simulation result of a wafer cooling effect in the case of varying an emissivity of a heat absorption layer.

### DETAILED DESCRIPTION OF THE EMBODIMENTS

Hereinafter, embodiments of the present invention will be described with reference to the accompanying drawings.

### First Embodiment

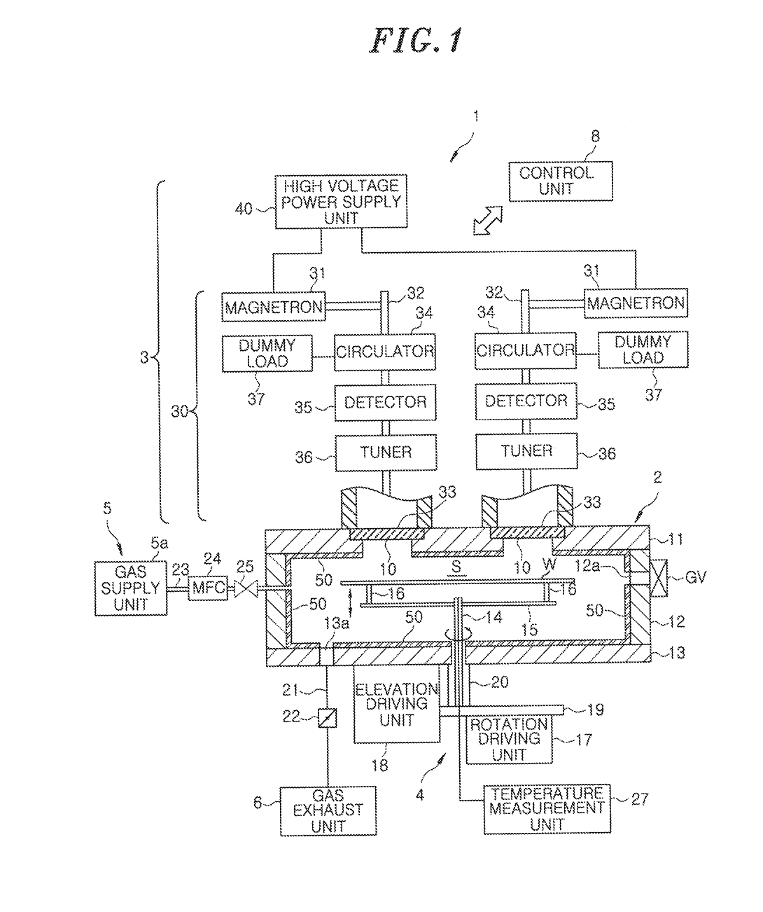

First, a schematic configuration of a microwave processing apparatus in accordance with a first embodiment of the present invention will be described with reference to FIG. 1. FIG. 1 is a cross sectional view showing a schematic configuration of a microwave processing apparatus of the present embodiment. A microwave processing apparatus 1 of the present embodiment performs an annealing process on, e.g., a semiconductor wafer for a semiconductor device (hereinafter, simply referred to as “wafer”) by irradiating microwaves on the wafer in accordance with a plurality of consecutive operations.

The microwave processing apparatus 1 includes: a processing chamber 2 accommodating a wafer W as an object to be processed; a microwave introducing unit 3 for introducing a microwave into the processing chamber 2; a support unit 4 for supporting the wafer W in the processing chamber 2; a gas supply mechanism 5 for supplying a gas into the processing chamber 2; a gas exhaust unit 6 for evacuating the processing chamber 2 to reduce a pressure therein; and a control unit 8 for controlling the respective components of the microwave processing apparatus 1.

(Processing Chamber)

The processing chamber 2 is made of a metal material for reflecting a microwave. The processing chamber 2 is made of, e.g., aluminum, aluminum alloy or the like.

The processing chamber 2 includes a plate-shaped ceiling portion 11 serving as an upper wall, bottom portion 13 serving as a bottom wall, a square tube-shaped sidewall 12 for connecting the ceiling portion 11 and the bottom portion 13, a plurality of microwave inlet ports 10 vertically extending through the ceiling portion 11, a loading/unloading port 12a provided at the sidewall 12, and a gas exhaust port 13a provided at the bottom portion 13. Further, the sidewall 12 may have a cylindrical shape. Through the loading/unloading port 12a, the wafer W is transferred between the processing chamber 2 and a transfer chamber (not shown) adjacent to the processing chamber 2. A gate valve GV is provided between the processing chamber 2 and the transfer chamber (not shown). The gate valve GV has a function of opening/closing the loading/unloading port 12a. The gate valve GV in a closed state airtightiy seals the processing chamber 2, and the gate valve GV in an open state allows the wafer W to be transferred between the processing chamber 2 and the transfer chamber (not shown).

(Support Unit)

The support unit 4 includes a pipe-shaped shaft 14 extending through an approximate center of the bottom portion 13 of the processing chamber 2 to the outside of the processing chamber 2, a plurality of arms 15 extending radially in a substantially horizontal direction at an upper end portion of the shaft 14, and a plurality of support pins 16 serving as support members that are detachably attached to the arms 15. The support unit 4 further includes a rotation driving unit 17 for rotating the shaft 14, an elevation driving unit 18 for vertically displacing the shaft 14, and a movable connection unit 19 for connecting the rotation driving unit 17 and the elevation driving unit 18 while supporting the shaft 14. The rotation driving unit 17, the elevation driving unit 18 and the movable connection unit 19 are provided outside the processing chamber 2. Further, a seal mechanism 20, e.g., a bellows or the like, may be provided around a portion where the shaft 14 penetrates through the bottom portion 13 in order to set the inside of the processing chamber 2 in a vacuum state.

A plurality of (three in the present embodiment) pins 16 supports the wafer W while being in contact with the bottom surface of the wafer W in the processing chamber 2. The support pins 16 are provided such that the upper end portions thereof are arranged in the circumferential direction of the wafer W. Each of the support pins 16 is detachably attached to the rod-shaped arm 15. The support pins 16 and the arms 15 are made of a dielectric material. The dielectric material forming the support pins 16 and the arms 15 may be, e.g., quartz, ceramic or the like. Further, the number of the support pins 16 is not limited to three as long as the support pins 16 can stably support the wafer W.

In the support unit 4, the shaft 14, the arms 15, the rotation driving unit 17 and the movable connection unit 19 constitute a rotation mechanism for horizontally rotating the wafer W supported by the support pins 16. The support pins 16 and the arms 15 are rotated about the shaft 14 by driving the rotation driving unit 17, and each of the support pins 16 is rotated horizontally in circular motion (revolved). Further, in the support unit 4, the shaft 14, the arms 15, the elevation driving unit 18 and the movable connection unit 19 constitute a height position adjusting mechanism for adjusting a height position of the wafer W supported by the support pins 16. The support pins 16 and the arms 15 are vertically displaced together with the shaft 14 by driving the elevation driving unit 18. Further, in the microwave processing apparatus 1, the rotation driving unit 17, the elevation driving unit 18 and the movable connection unit 19 are not essential and may be omitted.

The rotation driving unit 17 is not particularly limited as long as it can rotate the shaft 14, and may include, e.g., a motor (not shown) or the like. The elevation driving unit 18 is not particularly limited as long as it can vertically move the shaft 14 and the movable connection unit 19, and may include, e.g., a ball screw (not shown) or the like. The rotation driving unit 17 and the elevation driving unit 18 may be formed as one unit, and the configuration that does not include the movable connection unit 19 may be employed. Further, the rotation mechanism for horizontally rotating the wafer and the height position adjusting mechanism for adjusting the height position of the wafer W may have different configurations as long as their functions can be realized.

(Gas Exhaust Unit)

The gas exhaust unit 6 includes a vacuum pump, e.g., a dry pump or the like. The microwave processing apparatus 1 includes a gas exhaust line 21 which connects the as exhaust port 13a to the as exhaust unit 6, and a pressure control valve 22 disposed on the gas exhaust line 21. By driving the vacuum pump of the as exhaust unit 6, the inside of the processing chamber 2 is vacuum-exhausted. Further, the microwave processing apparatus 1 may perform a process under an atmospheric pressure. In that case, the vacuum pump is not necessary. Instead of using the vacuum pump such as a dry pump or the like as the gas exhaust unit 6, it is possible to use gas exhaust equipments provided at a facility where the microwave processing apparatus 1 is installed.

(Gas Supply Mechanism)

The microwave processing apparatus 1 further includes a gas supply mechanism 5 for supplying a gas into the processing chamber 2. The gas supply mechanism 5 includes: a gas supply unit 5a having a gas supply source (not shown); and a plurality of lines 23 (only one shown), for introducing a processing gas into the processing chamber 2, connected to the gas supply unit 5a. The lines 23 are connected to the sidewall 12 of the processing chamber 2. The gas supply mechanism 5 further includes a mass flow controller (MFC) 24, and one or more opening/closing valves (only one shown) which are disposed on the line 23. A flow rate of the gas introduced into the processing chamber is controlled by the mass flow controller 24 and the opening/closing valve 25.

The gas supply device 5a is configured to supply a gas of, e.g., N₂, Ar, He, Ne, O₂, H₂ or the like, as a processing gas or a cooling gas, into the processing chamber 2 through the lines 23 in a side flow type. Further, the gas supply into the processing chamber 2 may be performed by a gas supply device provided at, e.g., a position opposite to the wafer W (e.g., the ceiling portion 11). Moreover, an external gas supply device that is not included in the configuration of the microwave processing apparatus 1 may be used instead of the gas supply device 5a.

(Temperature Measurement Unit)

The microwave processing apparatus 1 further includes a plurality of radiation thermometers (not shown) for measuring a surface temperature of the wafer W, and a temperature measurement unit 27 connected to the radiation thermometers.

(Microwave Radiation Space)

In the microwave processing apparatus 1 of the present embodiment, a microwave radiation space S is formed in the processing chamber 2. In the microwave radiation space S, microwaves are radiated from a plurality of microwave inlet ports 10 provided at the ceiling portion 11. Since the ceiling portion 11, the sidewall 12 and the bottom portion of the processing chamber are made of metallic materials, the microwaves are reflected, and scattered in the microwave radiation space S.

(Microwave Introducing Unit)

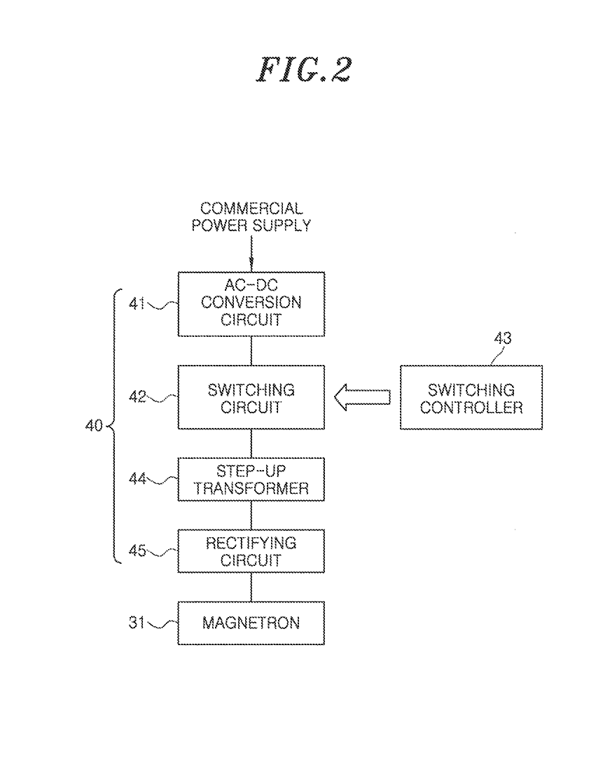

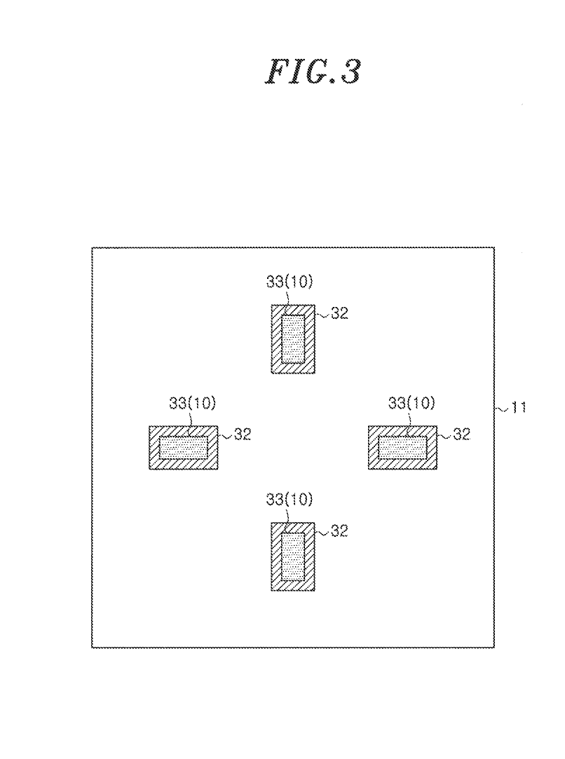

Hereinafter, the configuration of the microwave introducing unit 3 will be described with reference to FIGS. 1 to 3. FIG. 2 explains a schematic configuration of a high voltage power supply unit of the microwave introducing unit 3. FIG. 3 is a top view showing the top surface of the ceiling portion 11 of the processing chamber 2 shown in FIG. 1.

The microwave introducing unit 3 is provided at an upper portion of the processing chamber 2 and serves as a microwave introducing unit for introducing an electromagnetic wave (microwave) into the processing chamber 2. As shown in FIG. 1, the microwave introducing unit 3 includes a plurality of microwave units 30 for introducing microwaves into the processing chamber 2, and a high voltage power supply unit 40 connected to the microwave units 30.

(Microwave Unit)

In the present embodiment, the microwave units 30 have the same configuration. Each of the microwave units 30 includes a magnetron 31 for generating a microwave for processing the wafer W, a waveguide 32 for transmitting the microwave generated, by the magnetron 31 to the processing chamber 2, and a transmission window 33 fixed to the ceiling portion 11 to block the microwave inlet ports 10. The magnetron 31 corresponds to a microwave source of the present invention.

As shown in FIG. 3, in the present embodiment, the processing chamber 2 has four microwave inlet ports 10 that are spaced apart from each other at a regular interval in a circumferential direction so as to form an approximately cross shape as a whole in the ceiling portion 11. Each of the microwave inlet ports 10 has a rectangular shape with short sides and long sides in a plan view. The microwave inlet ports 10 may have different sizes or different ratios between the long sides and the short sides. However, the four microwave inlet port 10 preferably have the same size and the same shape in order to obtain uniformity of the annealing process for the wafer W and improve controllability. Further, in the present embodiment, the microwave units 30 are connected to the microwave inlet ports 10, respectively. In other words, the number of the microwave units 30 is four.

The magnetron 31 has an anode and a cathode (both not shown) to which a high voltage from the high voltage power supply unit 40 is applied. Further, as for the magnetron 31, it is possible to use one capable of oscillating microwaves of various frequencies. The frequency of the microwaves generated by the magnetron 31 is optimally selected in accordance with processing types. For example, in case of an annealing process, the microwaves having a high frequency of 2.45 GHz, 5.8 GHz or the like are preferable, and the microwaves having a high frequency of 5.8 GHz are more preferable.

The waveguide 32 has a rectangular or square shape in section and extends upward from the top surface of the ceiling portion 11 of the processing chamber 2. The magnetrons 31 are respectively connected to the upper end portions of the waveguides 32. The lower ends of the waveguides 32 contact with the top surface of the transmission window 33. The microwaves generated by the magnetrons 31 are introduced into the processing chamber 2 through the waveguides 32 and the transmission windows 33.

The transmission window 33 is made of a dielectric material. As for the material of the transmission window 33, it is possible to use, e.g., quartz, ceramic or the like. The gap between the transmission window 33 and the ceiling portion 11 is airtightly sealed by a seal member (not shown). A distance from the bottom surface of the transmission window 33 to the surface of the wafer W supported by the support pins 16 is preferably set to, e.g., 25 mm or above, in view of suppressing direct radiation of microwaves to the wafer W. More preferably, the distance can be variably controlled within a range from 25 mm to 50 mm.

The microwave unit 30 further includes a circulator 34, a detector 35 and a tuner 36 which are arranged in the path of the waveguide 32, and a dummy load 37 connected to the circulator 34. The circulator 34, the detector 35 and the tuner 36 are provided in that order from the upper end side of the waveguide 32. The circulator 34 and the dummy load 37 constitute an isolator for isolating reflected waves from the processing chamber 2. In other words, the circulator 34 guides the reflected wave from the processing chamber 2 to the dummy load 37, and the dummy load 37 converts the reflected wave guided by the circulator 34 into heat.

The detector 35 detects the reflected wave from she processing chamber 2 in the waveguide 32. The detector 35 includes, e.g., an impedance monitor, specifically, a standing wave monitor for detecting an electric field of a standing wave in the waveguide 32. The standing wave monitor may include, e.g., three bins protruding into an inner space of the waveguide 32. The reflected wave from the processing chamber 2 can be detected by detecting the location, phase and intensity of the electric field, of the standing wave by using the standing wave monitor. Further, the detector 35 may be formed by a directional coupler capable of detecting a traveling wave and a reflected wave.

The tuner 36 has a function of performing impedance matching between the magnetron 31 and the processing chamber 2. The impedance matching by the tuner 36 is performed based on the detection result of the reflected wave in the detector 35. The tuner 36 may include, e.g., a conductive plate (not shown) provided, to protrude into and retreat from the inner space of the waveguide 32. In that case, the impedance between the magnetron 31 and the processing chamber 2 can be controlled by adjusting the power of the reflected wave by controlling the protruding amount of the conductive plate into the inner space of the waveguide 32.

(High Voltage Power Supply Unit)

The high voltage power supply unit 40 supplies a high voltage to the magnetron 31 for generating a microwave. As shown in FIG. 2, the high voltage power supply unit 40 includes an AC-DC conversion circuit 41 connected to a commercial power supply, a switching circuit 42 connected to the AC-DC conversion circuit 41, a switching controller 43 for controlling an operation of the switching circuit 42, a step-up transformer 44 connected to the switching circuit 42, and a rectifying circuit 45 connected to the step-up transformer 44. The magnetron 31 is connected to the step-up transformer 44 via the rectifying circuit 45.

The AC-DC conversion circuit 41 is a circuit which rectifies an AC (e.g., three phase 200V AC) supplied from the commercial power supply and converts it to a direct current having a predetermined waveform. The switching circuit 42 controls on/off of the direct current converted by the AC-DC conversion circuit 41. In the switching circuit 42, the switching controller 43 performs phase-shift PWM (pulse width modulation) control or PAM (pulse amplitude modulation) control, thereby generating a pulsed voltage waveform. The step-up transformer 44 boosts the voltage waveform outputted from the switching circuit 42 to a predetermined level. The rectifying circuit 45 rectifies the voltage boosted by the step-up transformer 44 and supplies the rectified voltage to the magnetron 31.

(Heat Absorption Layer)

A heat absorption layer 50 is provided on the inner wall surfaces of the ceiling portion 11, the sidewall 12 and the bottom portion 13 of the processing chamber 2. The heat absorption layer 50 is preferably provided at least on the wall surface of the member which faces the wafer W supported by the support pins 16 of the support unit 4 in the processing chamber 2 in order to increase the cooling efficiency of the wafer W. Here, “facing the wafer W” denotes facing the top surface or the bottom surface of the wafer W. In the microwave processing apparatus 1 of the present embodiment, the member facing the wafer W supported by the support pins 16 of the support unit 4 corresponds to the ceiling portion 11 that faces the top surface of the wafer W at a position above the wafer W and the bottom portion 13 that faces the bottom surface of the wafer W at a position below the wafer W. Therefore, the heat absorption layer 50 may be provided on the inner wall surfaces of the ceiling portion 11 and the bottom portion 13. However, in the present embodiment, the heat absorption layer 50 is further provided on the inner wall surface of the sidewall 12.

Further, in view of obtaining a uniform cooling facilitation effect in the surface of the wafer W, the heat absorption layer 50 is preferably provided at least at a wafer-facing region of a member facing the wafer W. Here, in the case of projecting the contour of the wafer W onto, e.g., the inner wall surface of the ceiling portion 11, “wafer-facing region” denotes the projected region. Moreover, in the case of projecting the contour of the wafer W supported by the support pins 16 of the support unit 4 onto the inner wall surface of the bottom wall 13, “wafer-facing region” denotes the projected region. Furthermore, in the microwave processing apparatus of the present embodiment, the microwave inlet ports 10 are formed at the ceiling portion 11, so that the heat absorption layer 50 is formed on the entire inner wall surface of the ceiling portion 11 except the microwave inlet ports 10. Further, in the microwave processing apparatus 1 of the present embodiment, the gas exhaust port 13a is provided at the bottom portion 13, and the shaft 14 penetrates through the bottom portion 13. Therefore, the heat absorption layer 50 is formed at the entire inner wall surface of the bottom portion except the portions where the gas exhaust port 13a and the shaft 14 are installed.

The heat absorption layer 50 preferably has heat resistance up to, e.g., about 100° C., and is made of a material having a higher emissivity than that of the member facing the wafer W. As described above, the processing chamber 2 is made of metal such as aluminum, aluminum alloy or the like. Accordingly, the heat absorption layer 50 is preferably made of a material, having emissivity higher than those of these metals.

Moreover, the heat absorption layer 50 is preferably made of a material that easily transmits the microwave and reduces loss of the transmitted microwave. When the loss of the microwave in the heat absorption layer 50 is large, the microwave is consumed by the heat absorption layer 50. As a consequence, when the annealing process for the wafer W is performed in the microwave processing apparatus 1, the heating efficiency of the wafer W deteriorates. Therefore, the heat absorption layer 50 is preferably made of, e.g., a material having a dielectric loss tangent (tad) of 10⁻³ or less in the frequency of the microwave, i.e., 5.8 GHz, and a dielectric constant of 3 or less. When the dielectric loss tangent and the dielectric constant are within the above range, the deterioration of the heating efficiency of the wafer W can be prevented without affecting the behavior of the microwave in the processing chamber 2 by minimizing the loss of the microwave in the heat absorption layer 50.

The material of the heat absorption layer 50, which has heat resistance and low microwave loss and has an emissivity higher than the metal forming the processing chamber 2, may be a compound resin, e.g., fluorine resin, polyimide resin, polystyrene, polyethylene or the like. Particularly, the fluorine resin is preferable since it has a dielectric loss tangent of 10⁻³ or less in the frequency of the microwave, i.e., 5.8 GHz, and a dielectric constant of 3 or less, and thus can effectively extract heat from the wafer W during cooling while reducing the microwave loss in the annealing process. The fluorine resin having a low dielectric loss tangent and a low dielectric constant may be, e.g., polytetrafluoroethylene (PTFE), perfluoroalkoxylkane (PEA) or the like. For example, compared to aluminum having an emissivity of 0.09 which is generally used for the processing chamber 2, polytetrafluoroethylene (PIPE) with a thickness of 0.2 mm has an emissivity of about 0.68, so that larger heat absorption is expected compared to that on a rough aluminum surface.

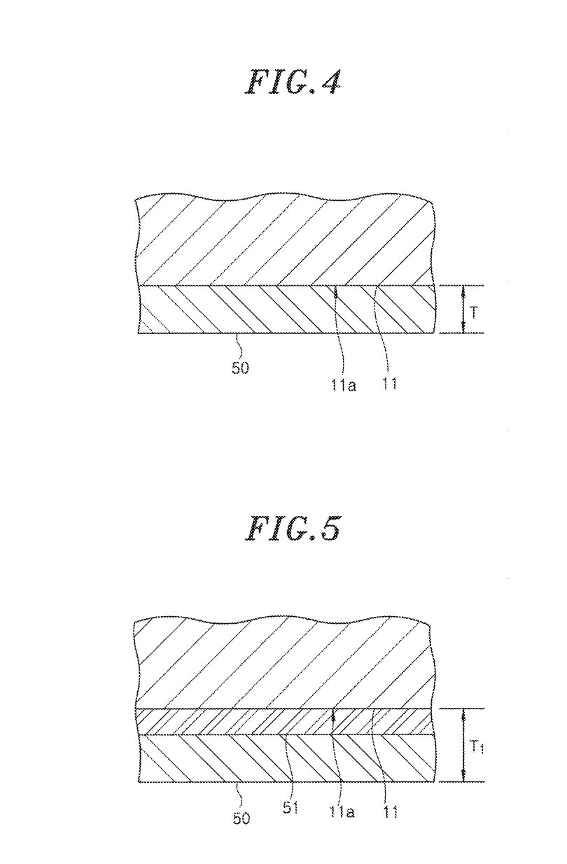

FIGS. 4 and 5 are enlarged cross sectional views of the ceiling portion 11 where the heat absorption layer 50 is formed. As shown in FIG. 4, the heat absorption layer 50 may be directly formed on an inner wall surface 11a of the ceiling portion 11. When the heat absorption layer 50 is directly formed on the inner wall surface 11a of the ceiling portion 11, the inner wall surface 11a is preferably roughened to ensure adhesivity between the inner wall surface 11a and the heat absorption layer 50.

Further, as shown in FIG. 5, the heat absorption layer 50 may be provided on the inner wall surface 11a of the ceiling portion 11 through a binder layer 51. As for the binder layer 51, it is possible to use a resin-based adhesive, e.g., polyamideimide resin, polyethersulfone resin, epoxy resin or the like. In the case of providing the heat absorption layer 50 on the inner wall surface 11a of the ceiling portion 11 through the binder layer 51 as described above, it is preferable to perform mirror processing on the inner wall surface 11a to increase the microwave reflection efficiency.

The thickness of the heat absorption layer 50 may be set in accordance with its material since it affects the emissivity. For example, when the heat absorption layer 50 is directly provided on the inner wall surface 11a of the ceiling portion 11 (see FIG. 4), if the heat absorption layer 50 is made of fluorine resin, the thickness T of the heat absorption layer 50 is preferably within a range from, e.g., 0.05 mm to 0.25 mm and more preferably within a range from, e.g., 0.08 mm to 0.2 mm, in view of improving the cooling efficiency of the wafer W by increasing the emissivity of the heat absorption layer 50 while minimizing the microwave loss.

Further, when the heat absorption layer 50 is indirectly provided on the inner wall surface 11a of the ceiling portion 11 through the binder layer 51 (see FIG. 5), if the heat absorption layer 50 is made of fluorine resin, the total thickness T₁ of the heat absorption layer 50 and the binder layer 51 is preferably within a range from, e.g., 0.01 mm to 0.015 mm and more preferably within a range from, e.g., 0.01 mm to 0.013 mm, in view of improving the cooling efficiency of the wafer W by increasing the emissivity of the heat absorption layer 50 while minimizing the microwave loss.

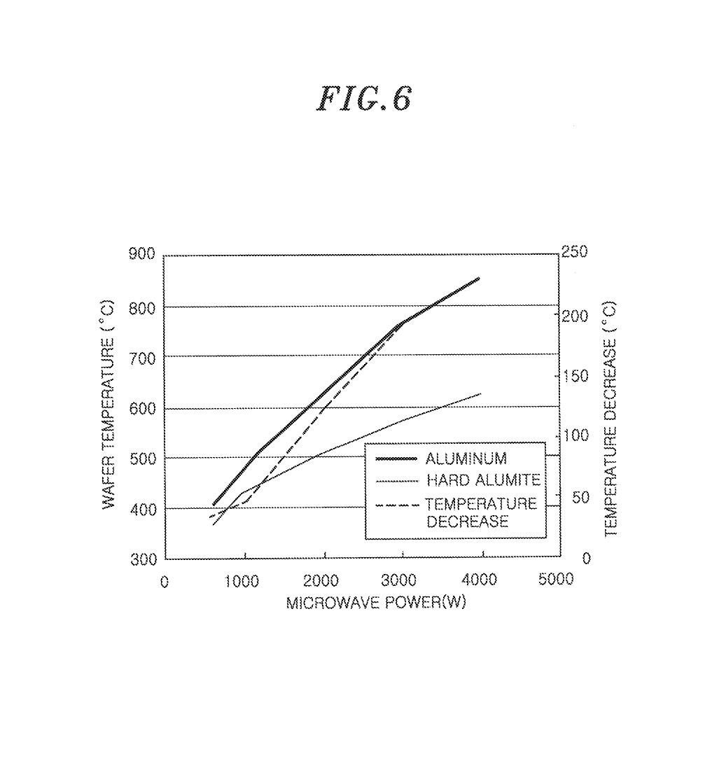

In a modification of the present embodiment, the heat absorption layer 50 may be formed of an alumite film obtained by performing alumite treatment (anodic oxidation treatment) on the inner wall surface of the processing chamber 2 which is made of aluminum, especially, a hard alumite film (emissivity of about 0.6). The hard alumite film has a dielectric loss tangent of about 0.001 in the frequency of the microwave, i.e., 5.8 GHz, and a dielectric constant of about 8. The thickness of the hard alumite film as the heat absorption layer 50 is preferably within a range from about, e.g., 30 μm to 100 μm, and more preferably within a range from about, e.g., 50 μm to 60 μm, in view of improving the cooling efficiency of the wafer W by increasing the emissivity of the heat absorption layer 50 while minimizing the microwave loss. FIG. 6 is a graph showing a result of a test that has measured the temperature of the wafer W by supplying the microwave into the processing chamber 2 having, on the inner wall surface 11a of the ceiling portion 11, the hard alumite film having a thickness of about 50 μm which serves as the heat absorption layer 50. In FIG. 6, a result of a test on an aluminum surface is also illustrated, for comparison. In FIG. 6, the left vertical axis indicates the temperature of the wafer W, and the right vertical axis indicates a temperature decrease on the aluminum surface in the case of providing the hard alumite layer. The horizontal axis in FIG. 6 indicates a microwave power. In this test, the microwaves having powers of about 600 W to 4000 W were supplied. It is clear from FIG. 6 that the cooling of the wafer W can be effectively performed by forming a hard alumite film as the heat absorption layer 50.

Although FIGS. 4 and 5 show the case of providing the heat absorption layer 50 at the ceiling portion 11 as an example, the case of providing the heat absorption layer 50 on the inner wall surfaces of the sidewall 12 and the bottom portion 13 is the same as the case of providing the heat absorption layer 50 at the ceiling portion 11.

(Control Unit)

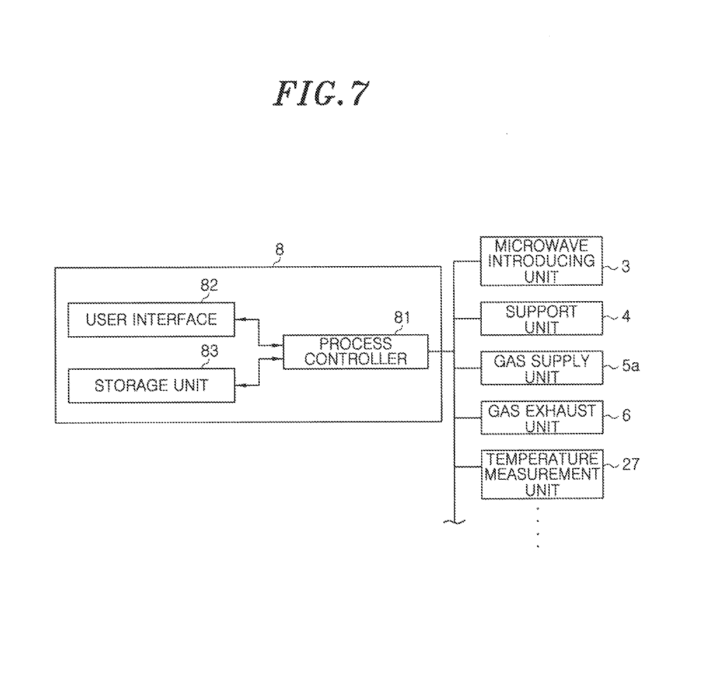

Each component of the microwave processing apparatus 1 is connected to and controlled by the control unit 8. The control unit 8 is typically a computer. FIG. 7 explains the configuration of the control unit 8 shown in FIG. 1. In the example shown in FIG. 7, the control unit 8 includes a process controller 81 having a CPU, a user interface 82 and a storage unit 83 connected to the process controller 81.

The process controller 81 integrally controls the components of the microwave processing apparatus 1 (e.g., the microwave introducing unit 3, the support unit 4, the gas supply device 5a, the as exhaust unit 6, the temperature measurement unit 27 and the like) which relate to the processing conditions, e.g., a temperature, a pressure, a gas flow rate, power of a microwave, a rotation speed of the wafer W and the like.

The user interface 82 includes a keyboard or a couch panel through which a process manager inputs commands to manage the microwave processing apparatus 1, a display for displaying an operation status of the microwave processing apparatus 1, and the like.

The storage unit 83 stores therein control programs (software) for implementing various processes performed by the microwave processing apparatus 1 under the control of the process controller 81, and recipes in which processing condition data and the like are recorded. The process controller 81 executes a certain control program or recipe retrieved from the storage unit 83 in response to an instruction from the user interface 82 when necessary. Accordingly, a desired process is performed in the processing chamber 2 of the microwave processing apparatus 1 under the control of the process controller 81.

The control programs and the recipes may be stored in a computer-readable storage medium, e.g., a CD-ROM, a hard disk, a flexible disk, a flash memory, a DVD, a Blu-ray disc, or the like. Further, the recipes may be transmitted online from another device via, e.g., a dedicated line, whenever necessary.

(Processing Sequence)

Hereinafter, the sequence of processes performed in the microwave processing apparatus 1 in the case of performing an annealing process on a wafer W will be described. First, a command to perform the annealing process in the microwave processing apparatus 1 is input from the user interface 82 to the process controller 81, for example. Next, the process controller 81 receives the command and retrieves a recipe stored in the storage unit 83 or a computer-readable storage medium. Then, the process controller 81 transmits control signals to the end devices of the microwave processing apparatus 1 (e.g., the microwave introducing unit 3, the support unit 4, the gas supply unit 5a, the gas exhaust unit 6 and the like) so that the annealing process can be performed under the conditions based on the recipe.

Thereafter, the gate valve CV is opened, and the wafer W is loaded into the processing chamber 2 through the gate valve CV and the loading/unloading port 12a by a transfer unit (not shown). Then, the wafer W is mounted on the support pins 16. The support pins 16 are vertically moved together with the shaft 14 and the arms 15 by driving the elevation driving unit 18, and the wafer W is set to a predetermined height. By driving the rotation driving unit 17 at this height, the wafer W is horizontally rotated at a predetermined speed. Further, the rotation of the wafer W may be non-consecutive. Next, the gate valve GV is closed, and the processing chamber 2 is vacuum-evacuated by the gas exhaust unit 6 when necessary. Then, the processing gas is introduced at a predetermined flow rate into the processing chamber 2 by the gas supply unit 5a. The inner space of the processing chamber 2 is controlled to a specific pressure by controlling the gas exhaust amount and the gas supply amount.

Next, a microwave is generated by applying a voltage from the high voltage power supply unit 40 to the magnetron 31. The microwave generated by the magnetron 31 propagates through the waveguide 32, and passes through the transmission window 33, and then is introduced into the microwave radiation space S above the rotating wafer W in the processing chamber 2. In the present embodiment, microwaves are sequentially generated by the magnetrons 31 and introduced into the processing chamber 2 through the microwave inlet ports 10. Further, a plurality of microwaves may be simultaneously generated by the magnetrons 31 and simultaneously introduced into the processing chamber 2 through the microwave inlet ports 10.

The microwaves introduced into the processing chamber 2 are irradiated to the rotating wafer W, so that the wafer W is rapidly heated by electromagnetic wave heating such as joule heating, magnetic heating, induction heating or the like. As a result, the wafer W is annealed. During the annealing process, the heat absorption layer 50 provided on the inner wall surfaces of the ceiling portion 11, the sidewall 12 and the bottom portion 13 of the processing chamber 2 effectively absorbs and extracts radiant heat from the wafer W. Accordingly, the excessive increase of the temperature of the wafer W can be suppressed, and the process in which heating and cooling are balanced can be carried out.

Further, during the annealing process, the wafer W may be rotated in a horizontal direction by the support unit 4 or the height position of the wafer W may be changed. By rotating the wafer W or changing the height positron of the wafer W during the annealing process, the non-uniform distribution of the microwave irradiated to the wafer W can be reduced and the heating temperature in the surface of the wafer W can become uniform. For example, by rotating the wafer W by the support unit 4 during the annealing process, the cooling can be performed while ensuring uniform temperature distribution in the surface of the wafer W. In the microwave processing apparatus 1 of the present embodiment, the ceiling portion 11 has the microwave inlet ports 10 and the heat absorption layer 50 cannot be provided at that portions. Therefore, the uniform cooling in the surface of the wafer W can be realized by rotating the wafer W. In addition, by changing the height position of the wafer W by the support unit 4 during the annealing process, the cooling efficiency by the heat absorption layer 50 can be controlled. For example, by lifting the wafer W to a cooling position different from a usual height position during the annealing process, the heat extraction amount from the wafer W can be increased. The height position adjustment of the wafer W is also effective in the case of providing the heat absorption layer 50 only at, e.g., the ceiling portion 11.

When the process controller 81 transmits a control signal to each end device of the microwave processing apparatus 1 to complete the annealing process, the generation of the microwave is stopped and, also, the rotation of the wafer W and the supply of the processing gas and the cooling gas are stopped.

Moreover, after the annealing process is completed, the wafer W can be cooled in a state where the wafer if is held on the support pins 16. The heat absorption layer 50 provided on the inner wall surfaces of the ceiling portion 11, the sidewall 12 and the bottom portion 13 of the processing chamber 2 effectively absorbs and extracts radiant heat from the wafer W. Accordingly, the cooling of the wafer W can be facilitated.

During the cooling process, the cooling can be performed while ensuring uniform temperature distribution in the surface of the wafer W by rotating the wafer W by the support unit 4.

Further, during the cooling process, the height position of the wafer W can be changed by the support unit 4. For example, the heat extraction amount from the wafer W can be increased by raising the wafer W to the cooling position different from the height position of the annealing process.

Moreover, during the cooling process, in order to facilitate the cooling of the wafer W, a cooling gas may be introduced from the gas supply unit 5a into the processing chamber 2, if necessary.

After the annealing or cooling process for a predetermined period of time is completed, the gate valve CV is opened, and the height position of the wafer W is adjusted by the support unit 4. Thereafter, the wafer W is unloaded by the transfer unit (not shown).

The microwave processing apparatus 1 can be suitably used for the annealing process for activating doping atoms injected into the diffusion layer or the like in the semiconductor device manufacturing process, for example.

As described above, the microwave processing apparatus 1 of the present embodiment can perform the cooling process of the wafer W in the processing chamber 2 during or after the annealing process for irradiating the microwave on the wafer W. During the cooling process, the temperature can be quickly decreased by allowing the heat absorption layer 50 provided on the inner wall surface of the processing chamber 2 to absorb heat from the wafer W. Especially, as the temperature of the wafer W is increased, the heat extraction amount is increased and the effective cooling can be carried out.

Further, since the uniform cooling facilitation effect in the surface of the wafer W is obtained by providing the heat absorption layer 50 at least at the wafer-facing region, the cooling time can be reduced while preventing warpage caused by heat distribution in the surface of the wafer W.

Moreover, as the volume, of the processing chamber 2 is increased, the surface area of the heat absorption layer 50 can be increased. Therefore, even if the processing chamber 2 is scaled up, excellent cooling effect can be maintained compared to the case of using the cooing gas.

As described above, in the microwave processing apparatus 1, it is possible to rapidly proceed to a next step for the annealed wafer W and also possible to increase a throughput in the case of switchingly processing a plurality of wafers W.

Further, although the heat absorption layer 50 is provided on the inner wall surfaces of the ceiling portion 11, the sidewall 12 and the bottom portion 13 of the processing chamber 2 in the microwave processing apparatus 1 shown in FIG. 1, the heat absorption layer 50 may be provided only on the inner wall surface 11a of the ceiling portion 11.

### Second Embodiment

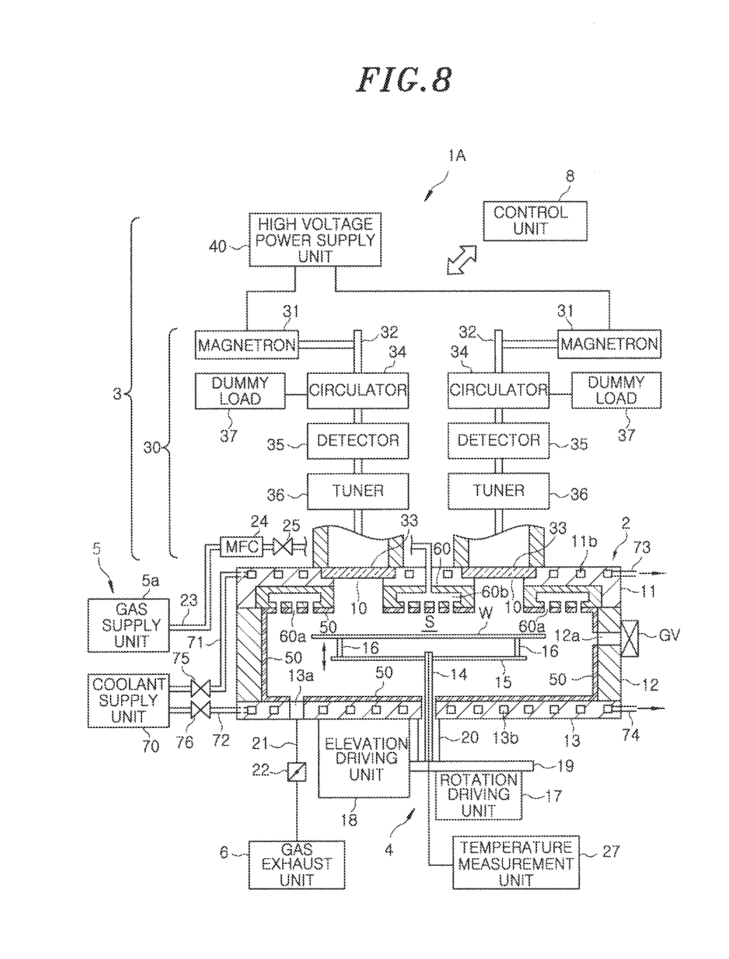

Hereinafter, a microwave processing apparatus in accordance with a second embodiment of the present invention will be described with reference to FIG. 8. FIG. 8 is a cross sectional view showing a schematic configuration of a microwave processing apparatus 1A of the present embodiment. The microwave processing apparatus 1A of the present embodiment is an apparatus for performing an annealing process by irradiating a microwave on, e.g., a wafer W, in accordance with a plurality of consecutive processes. In the following description, the difference between the microwave processing apparatus 1 of the first embodiment and the microwave processing apparatus 1A of the second embodiment will be mainly described. In FIG. 8, like reference numerals will refer to the same parts as those used in the microwave processing apparatus 1 of the first embodiment, and redundant description thereof will be omitted.

The microwave processing apparatus 1A of the present embodiment includes a shower head 60 as a gas introduction member. The shower head 60 introduces a gas into the processing chamber 2. The shower head 60 is installed at the ceiling portion 11 so as to face the wafer W. The shower head 60 has a plurality of gas holes 60a and a gas diffusion space 60b communicating with the gas holes 60a. The gas diffusion space 60b is connected to the line 23. Further, a mass flow controller (MFC) 24 and one or more opening/closing valves 25 (only one shown) are provided on the line 23. The flow rate of the gas supplied into the processing chamber 2 is controlled by the mass flow controller 24 and the opening/closing valve 25.

Further, the microwave processing apparatus 1A of the present embodiment includes a cooling mechanism for cooling the ceiling portion 11 and the bottom portion 13. In other words, the microwave processing apparatus 1A includes a coolant supply unit 70, supply lines 71 and 72 for supplying a coolant from the coolant supply unit 70, and circulation lines 73 and 74 for circulating the coolant. The supply line 71 is provided with a valve 75. The supply line 72 is provided with a valve 76. Moreover, although it is not illustrated, the circulation lines 73 and 74 are connected to the coolant supply unit 70.

Furthermore, a passage 11b for circulating the coolant is provided at the ceiling portion 11. The supply line 71 is connected to the passage 11b. The coolant is circulated to the coolant supply unit 70 through the passage 11b and the circulation line 73.

In addition, a passage 13b for circulating the coolant is provided at the bottom portion 13. The supply line 72 is connected to the passage 13b. The coolant is circulated to the coolant supply unit 70 through the passage 13b and the circulation line 74.

With the above configuration, in the microwave processing apparatus 1A, the coolant from the coolant supply unit 70 can be circulated through the supply line 71, the passage 11b in the ceiling portion 11, and the circulation line 73. Further, in the microwave processing apparatus 1A, the coolant from the coolant supply unit 70 can be circulated through the supply line 72, the passage 13b in the bottom portion 13 and the circulation line 74. The coolant supplied from the coolant supply unit 70 to the passages 11b and 13b is not particularly limited, and may be, e.g., water, a fluorine-based coolant or the like. Moreover, in the case of using water as the coolant, the water may be wasted without being circulated to the coolant supply unit 70 through the circulation lines 73 and 74.

In the microwave processing apparatus 1A, the heat absorption layer 50 is provided on the bottom surface of the shower head 60, and the inner wall surfaces of the sidewall 12 and the bottom portion 13 of the processing chamber 2. The heat absorption layer 50 is preferably provided at least on the wall surface of the member facing the wafer W supported by the support pins 16 of the support unit 4 in the processing chamber 2 in order to increase the cooling efficiency of the wafer W. In the microwave processing apparatus 1A of the present embodiment, the member facing the wafer W supported by the support pins 16 of the support unit 4 corresponds to the shower head 60 facing the top surface of the wafer W at a position above the wafer W and the bottom portion 13 facing the bottom surface of the wafer W at a position below the wafer. Therefore, the heat absorption layer 50 may be formed on the shower head 60 and the inner wall surface of the bottom portion 13. However, in the present embodiment, the heat absorption layer 50 is further provided on the inner wall surface of the sidewall 12.

Further, the heat absorption layer 50 is preferably provided at least at the wafer-facing region of the member facing the wafer W. In the microwave processing apparatus 1A of the present embodiment, the gas holes 60a are formed in the shower head 60. Therefore, the heat absorption layer 50 is formed on the entire wall surface of the shower head 60 except the gas holes 60a. The heat absorption layer 50 formed at the bottom portion 13 is the same as that of the first embodiment.

The sequence of the microwave process and the cooling process in the microwave processing apparatus 1A is the same as that in the first embodiment except that the gas is supplied by using the shower head 60 while supplying the coolant to the passage 11b of the ceiling portion 11 and the passage 13b of the bottom portion 13. In the microwave processing apparatus 1A, the ceiling portion 11 and the shower head 60 can be cooled by supplying the coolant from the coolant supply unit 70 to the passage 11b of the ceiling portion 11. Therefore, the cooling efficiency of the wafer W by the heat absorption layer 50 formed on the bottom surface of the shower head 60 can be increased. Further, in the microwave processing apparatus 1A, the bottom portion 13 can be cooled by supplying the coolant from the coolant supply unit 70 to the passage 13b of the bottom portion 13. Accordingly, the cooling efficiency of the wafer W by she heat absorption layer 50 formed on the inner wall surface of the bottom portion 13 can be increased.

Moreover, in the microwave processing apparatus 1A, the shower head 60 as the gas introduction member is installed to be fitted in the ceiling portion 11. However, the shower head may be provided as an individual member separated from the ceiling portion 11.

The other configurations and effects of the microwave processing apparatus 1A of the present embodiment are the same as those of the microwave processing apparatus 1 of the first embodiment, so that the description thereof will be omitted. Further, in the present embodiment as well, an alumite film can be used as the heat absorption layer 50.

In the microwave processing apparatus of the present invention, the wafer W can be effectively cooled without greatly affecting the behavior of the microwave in the processing chamber.

[Simulation Test]

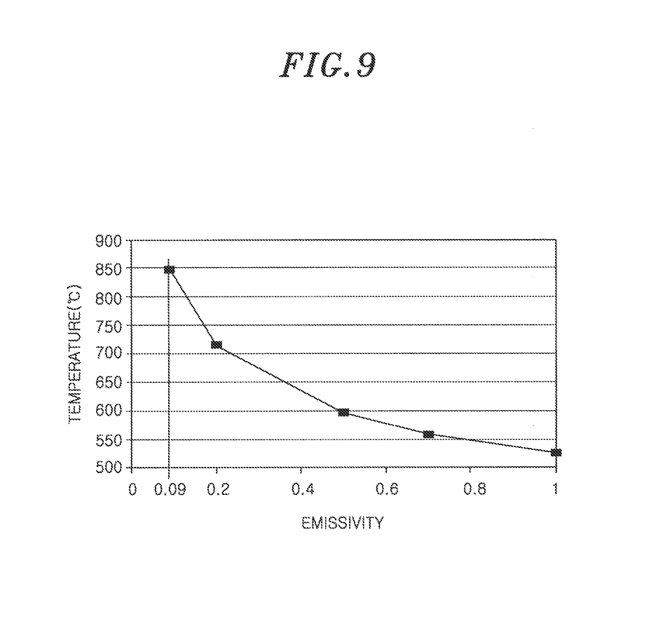

Hereinafter, a result of a simulation result that has examined she effect of the present invention will be described with reference to FIG. 9. In the microwave processing apparatus 1 having the configuration same as that of the first embodiment (FIG. 1), the effect of cooling the wafer W in the case of varying the emissivity of the heat absorption layer 50 was simulated. In this simulation, the temperature of the wafer W was calculated while introducing a predetermined amount heat into the wafer W consecutively and varying the emissivity of the inner surface of the processing chamber 2 to 0.2, 0.5, 0.7 and 1 on the basis of the emissivity of 0.09 of aluminum plain surface which is widely used for the processing chamber 2. In the simulation, the input heat to the wafer W was set to about 2250 W; the volume of the processing chamber 2 was set to 8 L; and the diameter of the wafer W was set to 300 mm. Further, the temperature of the wafer W was set to the temperature at the stable status.

The simulation test result is shown in FIG. 9. It is clear from FIG. 9 that the temperature of the wafer W is decreased and the cooling efficiency is improved by increasing the emissivity of the inner wall surface of the processing chamber 2. Thus, even when the heat absorption layer 50 is provided at the inner wall surface of the processing chamber 2, the effect of facilitating the temperature decrease of the wafer W can be obtained.

By providing the heat absorption layer 50 at least at the wafer-facing region, the uniform cooling facilitation effect in the surface of the wafer W can be obtained. Therefore, the cooling time can be reduced while preventing warpage caused by heat distribution in the surface of the wafer W or the like. Especially, as the temperature of the wafer W is increased, the heat extraction amount is increased and the effective cooling can be carried out.

Further, as the volume of the processing chamber 2 is increased, the surface area of the heat absorption layer 50 can be increased. Therefore, even if the processing chamber 2 is scaled up, excellent cooling effect can be maintained compared to the case of using a cooing gas.

Further, the present invention can be variously modified without be limited to the above embodiments. For example, the microwave processing apparatus of the present invention can be applied to a microwave processing apparatus which uses, e.g., a substrate for a solar cell panel or a substrate or a flat panel display as an object to be processed without being limited to the case of using a semiconductor wafer as an object to be processed.

Although the microwave processing apparatus 1 or 1A of the above embodiments is suitable for an annealing process, the present invention may also be applied to the case of performing a process for heating a wafer W by, e.g., an etching apparatus, an aching apparatus, a film forming apparatus or the like.

Further, the number of the microwave units 30 (the number of the magnetrons 31) or the number of the microwave inlet ports 10 in the microwave processing apparatus is not limited to that described in the above embodiments.

While the invention has been shown and described with respect to the embodiments, it will be understood by those skilled in the art that various changes and modification may be made without departing from the scope of the invention as defined in the following claims.

What is claimed is:

1. A microwave processing apparatus comprising:
a processing chamber configured accommodate an object to be processed, the processing chamber having an upper wall, a bottom wall and a sidewall;
a support member configured to support the object by contact with the object in the processing chamber;
a microwave introducing unit configured to generate a microwave tar processing the object and introduce the microwave into the processing chamber; and
a heat absorbing layer provided on a wall surface of a member facing the object supported by the supporting member in the processing chamber, the heat absorbing layer made of a material that transmits the microwave and has an emissivity higher than an emissivity of the member facing the object.

2. The microwave processing apparatus of claim 1, wherein the heat absorbing layer is formed by a compound resin or an alumite film.

3. The microwave processing apparatus of claim 2, wherein the compound resin is one or two or more elements selected from the group consisting of fluorine resin, polyimide resin, polystyrene and polyethylene.

4. The microwave processing apparatus of claim 1, wherein the material of the heat absorbing layer has a dielectric loss tangent of 10⁻³ or less at a frequency of the microwave and a dielectric constant of 3 or less.

5. The microwave processing apparatus of claim 1, wherein the heat absorbing layer has a thickness greater than or equal to 0.05 mm and smaller than or equal to 0.25 mm.

6. The microwave processing apparatus of claim 1, wherein the heat absorbing layer is provided at least at an object-facing region of the member facing the object.

7. The microwave processing apparatus of claim 6, wherein the member facing the object corresponds to the upper wall.

8. The microwave processing apparatus of claim 6, wherein the member facing the object corresponds to both of the upper wall and the bottom wall.

9. The microwave processing apparatus of claim 6, further comprising, as the member facing the object, a gas introducing member for introducing a gas into the processing chamber, the gas introducing member having a plurality of gas openings.

10. The microwave processing apparatus of claim 1, wherein the heat absorbing layer is further provided on an inner wall surface of the sidewall.

11. The microwave processing apparatus of claim 1, wherein the wall surface of the member facing the object is mirror-processed.

12. A microwave processing method, wherein in the processing chamber of the microwave processing apparatus described in claim 1, the microwave is irradiated to the object.

13. The microwave processing method of claim 12, wherein the microwave processing apparatus further comprises a rotation mechanism for rotating the object supported by the supporting member, and the microwave is irradiated while rotating the object.

14. The microwave processing method of claim 12, wherein the microwave processing apparatus further comprises a height position adjusting mechanism for adjusting a height position of the object supported by the supporting member, wherein the microwave is irradiated while changing the height position of the object between a first height position and a second height position different from the first height position.
